(19) United States
(12) Patent Application Publication
(10) Pub. No.: US 2014/0268545 A1
(43) Pub. Date: Sep. 18, 2014

(54) MODULAR SYNTHETIC JET EJECTOR AND SYSTEMS INCORPORATING THE SAME

(71) Applicant: Nuventix, Inc., Austin, TX (US)

(72) Inventors: Raghavendran Mahalingam, Austin, TX (US); Andrew Poynot, Austin, TX (US); Stephen P. Darbin, Austin, TX (US)

(73) Assignee: Nuventix, Inc., Austin, TX (US)

(21) Appl. No.: 14/185,601

(22) Filed: Feb. 20, 2014

Related U.S. Application Data
(60) Provisional application No. 61/768,090, filed on Feb. 22, 2013.

(51) Int. Cl. H05K 7/20; G06F 1/20

(52) U.S. Cl. CPC H05K 7/20136; G06F 1/20
USPC 361/679.47; 361/691; 361/679.46; 165/76

(57) ABSTRACT

A synthetic jet ejector (501) is provided which includes a diaphragm (503) and a chassis (505). The chassis has first and second major surfaces which are equipped with a set of interlocking features (509) such that a first instance of the synthetic jet ejector releasably attaches to a second instance of the synthetic jet ejector by way of the interlocking features.

### CROSS-REFERENCE TO RELATED APPLICATION

This application claims the benefit of priority from U.S. provisional application No. 61/768,090, filed Feb. 22, 2013, having the same title, and the same inventors, and which is incorporated herein by reference in its entirety.

### FIELD OF THE DISCLOSURE

The present disclosure relates generally to synthetic jet ejectors, and more particularly to versatile and modular synthetic jet ejectors and systems incorporating the same.

### BACKGROUND OF THE DISCLOSURE

A variety of thermal management devices are known to the art, including conventional fan based systems, piezoelectric systems, and synthetic jet ejectors. The latter type of system has emerged as a highly efficient and versatile thermal management solution, especially in applications where thermal management is required at the local level.

Various examples of synthetic jet ejectors are known to the art. Earlier examples are described in U.S. Pat. No. 5,758,823 (Glezer et al.), entitled “Synthetic Jet Actuator and Applications Thereof”; U.S. Pat. No. 5,894,990 (Glezer et al.), entitled “Synthetic Jet Actuator and Applications Thereof”; U.S. Pat. No. 5,988,522 (Glezer et al.), entitled Synthetic Jet Actuators for Modifying the Direction of Fluid Flows”; U.S. Pat. No. 6,056,204 (Glezer et al.), entitled “Synthetic Jet Actuators for Mixing Applications”; U.S. Pat. No. 6,123,145 (Glezer et al.), entitled Synthetic Jet Actuators for Cooling Heated Bodies and Environments”; and U.S. Pat. No. 6,588,497 (Glezer et al.), entitled “System and Method for Thermal Management by Synthetic Jet Ejector Channel Cooling Techniques”.

Further advances have been made in the art of synthetic jet ejectors, both with respect to synthetic jet ejector technology in general and with respect to the applications of this technology. Some examples of these advances are described in U.S. 20100263838 (Mahalingam et al.), entitled “Synthetic Jet Ejector for Augmentation of Pumped Liquid Loop Cooling and Enhancement of Pool and Flow Boiling”; U.S. 20100039012 (Grimm), entitled “Advanced Synjet Cooler Design For LED Light Modules”; U.S. 20100033071 (Heffington et al.), entitled “Thermal management of LED Illumination Devices”; U.S. 20090141065 (Darbin et al.), entitled “Method and Apparatus for Controlling Diaphragm Displacement in Synthetic Jet Actuators”; U.S. 20090109625 (Booth et al.), entitled Light Fixture with Multiple LEDs and Synthetic Jet Thermal Management System”; U.S. 20090084866 (Grimm et al.), entitled Vibration Balanced Synthetic Jet Ejector”; U.S. 20080295997 (Heffington et al.), entitled Synthetic Jet Ejector with Viewing Window and Temporal Aliasing”; U.S. 20080219007 (Heffington et al.), entitled “Thermal Management System for LED Array”; U.S. 20080151541 (Heffington et al.), entitled “Thermal Management System for LED Array”; U.S. 20080043061 (Glezer et al.), entitled “Methods for Reducing the Non-Linear Behavior of Actuators Used for Synthetic Jets”; U.S. 20080009187 (Grimm et al.), entitled “Moldable Housing design for Synthetic Jet Ejector”; U.S. 20080006393 (Grimm), entitled Vibration Isolation System for Synthetic Jet Devices”; U.S. 20070272393 (Reichenbach), entitled “Electronics Package for Synthetic Jet Ejectors”; U.S. 20070141453 (Mahalingam et al.), entitled “Thermal Management of Batteries using Synthetic Jets”; U.S. 20070096118 (Mahalingam et al.), entitled “Synthetic Jet Cooling System for LED Module”; U.S. 20070081027 (Beltran et al.), entitled “Acoustic Resonator for Synthetic Jet Generation for Thermal Management”; U.S. 20070023169 (Mahalingam et al.), entitled “Synthetic Jet Ejector for Augmentation of Pumped Liquid Loop Cooling and Enhancement of Pool and Flow Boiling”; U.S. 20070119573 (Mahalingam et al.), entitled “Synthetic Jet Ejector for the Thermal Management of PCI Cards”; U.S. 20070119575 (Glezer et al.), entitled “Synthetic Jet Heat Pipe Thermal Management System”; U.S. 20070127210 (Mahalingam et al.), entitled “Thermal Management System for Distributed Heat Sources”; U.S. 20070141453 (Mahalingam et al.), entitled “Thermal Management of Batteries using Synthetic Jets”; U.S. Pat. No. 7,252,140 (Glezer et al.), entitled “Apparatus and Method for Enhanced Heat Transfer”; U.S. Pat. No. 7,606,029 (Mahalingam et al.), entitled “Thermal Management System for Distributed Heat Sources”; U.S. Pat. No. 7,607,470 (Glezer et al.), entitled “Synthetic Jet Heat Pipe Thermal Management System”; U.S. Pat. No. 7,760,499 (Darbin et al.), entitled “Thermal Management System for Card Cages”; U.S. Pat. No. 7,768,779 (Heffington et al.), entitled “Synthetic Jet Ejector with Viewing Window and Temporal Aliasing”; U.S. Pat. No. 7,784,972 (Heffington et al.), entitled “Thermal Management System for LED Array”; and U.S. Pat. No. 7,819,556 (Heffington et al.), entitled “Thermal Management System for LED Array”.

### BRIEF DESCRIPTION OF THE DRAWINGS

FIGS. 1A-1C are illustrations depicting the manner in which a synthetic jet actuator operates.

FIG. 2 is a top view of a laptop which utilizes synthetic jet ejectors for spot or skin cooling.

FIG. 3 is a side view of a segment of the laptop of FIG. 2.

FIG. 4 is (from top to bottom) a side view and top view of a channel for a synthetic jet ejector in the laptop of FIG. 2.

FIG. 5 is an illustration of two systems utilized to generate the data depicted in the graphs of FIGS. 6-8; the first of the two systems is a fan-based thermal management system, and the second of the two systems is a fan-based thermal management system which is augmented by a synthetic jet ejector.

FIG. 6 is a graph showing heat dissipated at 70° C. as a function of flow rate (in cubic feet per minute) for the two systems of FIG. 5.

FIG. 7 is a graph showing thermal effectiveness as a function of flow rate (in cubic feet per minute) for the two systems of FIG. 5.

FIG. 8 is a graph showing heat transfer coefficient as a function of flow rate (in cubic feet per minute) for the two systems of FIG. 5.

FIG. 9 is an illustration of a portable device equipped with a synthetic jet based thermal management system.

FIG. 10 is an illustration of a synthetic jet ejector having a modular design.

FIG. 11 is an illustration showing various configurations which the modular synthetic jet ejector of FIG. 10 can be assembled into.

### SUMMARY OF THE DISCLOSURE

In one aspect, a device is provided which comprises (a) a plurality of heat sources arranged in a channel, wherein each heat source has a top; and (b) a synthetic jet ejector disposed in said channel; wherein said synthetic jet ejector directs a synthetic jet across the tops of said heat sources.

In another aspect, a computer is provided which comprises (a) a plurality of heat sources; (b) a heat sink spaced apart from said heat sources; (c) a plurality of thermal conductors, each of which is in thermal contact with said heat sink and one of said heat sources; and (d) a synthetic jet ejector which directs a synthetic jet onto or across a surface of said heat sink.

In a further aspect, a synthetic jet ejector is provided which comprises (a) a diaphragm; and (b) a chassis having first and second major surfaces which are equipped with a first set of interlocking features such that a first instance of the synthetic jet ejector releasably attaches to a second instance of the synthetic jet ejector by way of said first set of interlocking features.

### DETAILED DESCRIPTION

The structure of a synthetic jet ejector may be appreciated with respect to FIG. 1a. The synthetic jet ejector 101 depicted therein comprises a housing 103 which defines and encloses an internal chamber 105. The housing 103 and chamber 105 may take virtually any geometric configuration, but for purposes of discussion and understanding, the housing 103 is shown in cross-section in FIG. 1a to have a rigid side wall 107, a rigid front wall 109, and a rear diaphragm 111 that is flexible to an extent to permit movement of the diaphragm 111 inwardly and outwardly relative to the chamber 105. The front wall 109 has an orifice 113 therein which may be of various geometric shapes. The orifice 113 diametrically opposes the rear diaphragm 111 and fluidically connects the internal chamber 105 to an external environment having ambient fluid 115.

The movement of the flexible diaphragm 111 may be controlled by any suitable control system 117. For example, the diaphragm may be moved by a voice coil actuator. The diaphragm 111 may also be equipped with a metal layer, and a metal electrode may be disposed adjacent to, but spaced from, the metal layer so that the diaphragm 111 can be moved via an electrical bias imposed between the electrode and the metal layer. Moreover, the generation of the electrical bias can be controlled by any suitable device, for example but not limited to, a computer, logic processor, or signal generator. The control system 117 can cause the diaphragm 111 to move periodically or to modulate in time-harmonic motion, thus forcing fluid in and out of the orifice 113.

Alternatively, a piezoelectric actuator could be attached to the diaphragm 111. The control system would, in that case, cause the piezoelectric actuator to vibrate and thereby move the diaphragm 111 in time-harmonic motion. The method of causing the diaphragm 111 to modulate is not particularly limited to any particular means or structure.

The operation of the synthetic jet ejector 101 will now be described with reference to FIG. 1b-FIG. 1c. FIG. 1b depicts the synthetic jet ejector 101 as the diaphragm 111 is controlled to move inward into the chamber 105, as depicted by arrow 125. The chamber 105 has its volume decreased and fluid is ejected through the orifice 113. As the fluid exits the chamber 105 through the orifice 113, the flow separates at the (preferably sharp) edges of the orifice 113 and creates vortex sheets 121. These vortex sheets 121 roll into vortices 123 and begin to move away from the edges of the orifice 109 in the direction indicated by arrow 119.

FIG. 1c depicts the synthetic jet ejector 101 as the diaphragm 111 is controlled to move outward with respect to the chamber 105, as depicted by arrow 127. The chamber 105 has its volume increased and ambient fluid 115 rushes into the chamber 105 as depicted by the set of arrows 129. The diaphragm 111 is controlled by the control system 117 so that, when the diaphragm 111 moves away from the chamber 105, the vortices 123 are already removed from the edges of the orifice 113 and thus are not affected by the ambient fluid 115 being drawn into the chamber 105. Meanwhile, a jet of ambient fluid 115 is synthesized by the vortices 123, thus creating strong entrainment of ambient fluid drawn from large distances away from the orifice 109.

Despite the many advances in synthetic jet ejector technology, a need for further advances in this technology still exists. For example, challenges exist in the implementation of synthetic jet based thermal management systems in laptop and handheld devices, where spatial and geometric constraints make conventional thermal management systems impractical. Similarly, a need exists in the art for a means by which synthetic jet ejectors may be readily modified by end users according to constrains imposed by the end use application, without necessitating a redesign or customization of the synthetic jet ejector or thermal management system. These needs may be met by the systems and methodologies disclosed herein.

It has now been found that synthetic jet ejectors may be utilized advantageously to augment the fluidic flow provided by fan-based thermal management systems—especially in devices having spatial or design constraints—through the provision of channels, passageways or other measures in the host device. This is especially so in such applications involving the thermal management of computing devices, where the turbulent, localized flow provided by synthetic jet ejectors complements the global fluidic flow provided by fans by enhancing heat transfer through boundary layer disruption along the surfaces of a heat sink.

FIGS. 2-4 illustrate a particular, non-limiting embodiment of a laptop computer 201 which incorporates an embodiment of a thermal management system in accordance with the teachings herein. The laptop computer 201 in this particular embodiment includes a chassis 203, an inlet 205 (disposed on the bottom of the laptop 201), an outlet 207 (disposed on the side of the laptop 201), a fan 209 which drives air from the inlet 205 to the outlet 207 through a heat exchanger 211, a hard disk drive (HDD) 213, a battery 215, a DVD 217, memory cards 219, and a motherboard 221. The motherboard 221 has mounted on it a central processing unit (CPU) 223 with associated first voltage regulator (VR1) 225 and second voltage regulator (VR2) 227, a memory controller hub (MCH) 229, a graphics card 231, an input/output controller hub (ICH) 233, a system voltage regulator 235, and a PCMCIA (Personal Computer Memory Card International Association) card 237.

With reference to FIG. 3, the memory cards 219 in the laptop computer 201 of FIG. 2 are disposed beneath the motherboard 221 on a platform 239 which is spaced apart from the motherboard 221. In the particular embodiment depicted, the gap between the motherboard 221 and the platform 239 is about 1.5 mm, and the gap between the upper surface of the memory cards 219 and the motherboard 221 is about 1 mm, although it will be appreciated that the systems and methodologies disclosed herein are not necessarily limited to any particular dimensions. This gap creates a channel 241 through which a flow of air may be created for thermal management purposes, and which has inlet 211 and outlet 213 disposed on opposing ends thereof.

With reference to FIG. 4, a synthetic jet ejector 243 is disposed on one side of the channel 241 and operates to create one or more synthetic jets 245 which are directed along the longitudinal axis of the channel 241. The synthetic jets 245 create turbulence in the ambient fluid, thus disrupting the thermal boundary layer across the surfaces of the memory cards 219 and enhancing thermal transfer between the surfaces of the memory cards 219 and the ambient fluid, where it may be rejected to the external environment.

The thermal management system further includes the fan 215 (see FIG. 2) which is adapted to create a global flow of air from the inlet 211 to the outlet 213, and a synthetic jet ejector 243 which is disposed in the channel 241 and which is adapted to augment the global flow of air. More specifically, the synthetic jet ejector 243 directs one or more synthetic jets 245 across the tops of the heat sources (in this case, memory cards 219), and in doing so disrupts the boundary layer at the interface between the heat source and the airflow in the channel 241. This, in turn, improves the rate of heat transfer from the heat source to the air.

FIGS. 5-8 illustrate the improvement in heat dissipation, thermal effectiveness and heat transfer coefficient, respectively, in a system in which a synthetic jet ejector is utilized to augment a fan-based thermal management system. The data was derived from tests on the systems 301, 303 depicted in FIG. 5, in which a wall 305 has a first side 307 that is heated (i.e., exposed to a heat source), and a second side 309 that is exposed to a fluidic flow. In the system 301 depicted in FIG. 5(a), a fan 311 (or “blower”) is utilized alone to provide the fluidic flow, while in the system 303 of FIG. 5(b), the flow created by the fan (not shown) is augmented by a synthetic jet ejector 313. As seen in FIGS. 6-8, when the system is augmented with a synthetic jet ejector as in the system 303 of FIG. 5(b), notable enhancements in performance are achieved across a range of conditions.

FIG. 6 illustrates the amount of heat dissipated across the wall 303 in the systems of FIGS. 5(a) and 5(b) at 70° C. as a function of flow rate (in cubic feet per minute). As seen therein, at lower flow rates, the heat dissipated by the two systems is comparable. However, at higher flow rates, the amount of heat dissipation achieved with the system of FIG. 5(b), in which fluidic flow is augmented with a synthetic jet ejector, is substantially higher. Indeed, at flow rates above about 0.2 CFM, the percent improvement in heat dissipation achieved with the system of FIG. 5(b) is about 30-45% higher than that achieved with the system of FIG. 5(a).

FIG. 7 illustrates the thermal effectiveness (a unitless measure of the efficiency with which heat is transported across the wall 303) in the systems of FIGS. 5(a) and 5(b) as a function of flow rate (in CFM). As seen therein, the thermal effectiveness of the system of FIG. 5(b) is greater than that of the system of FIG. 5(a) across all flow rates.

FIG. 8 illustrates the heat transfer coefficient (that is, the proportionality coefficient between the heat flux and the temperature difference) in the systems of FIGS. 5(a) and 5(b) as a function of Reynolds Number (Re). As seen therein, the heat transfer coefficients of the system of FIG. 5(b) are higher than those of the system of FIG. 5(a), with the difference being especially pronounced at higher Reynolds numbers.

FIG. 9 illustrates how a thermal management system of the type disclosed herein may be modified to accommodate the spatial and geometric constraints of a hand-held device which may be, for example, a smart phone, a personal digital assistant, a handheld computer, or the like. The device 401 depicted therein has a chassis 403 within which is disposed a plurality of heat sources 405, each of which is in thermal communication with a heat sink 407 by way of a thermal conductor 409. The thermal conductors 409 preferably comprise graphene, but may be any other suitable thermally conductive material.

A synthetic jet ejector 413 is provided which is disposed adjacent to the heat sink 407, and which may also act as the acoustical speaker for the device 401. The synthetic jet ejector 413 is preferably adapted to direct a synthetic jet 411 into each of the channels formed by adjacent pairs of heat fins in the heat sink 407. Consequently, heat from the heat sources 405 is transferred to the heat sink 407 and then rejected to the ambient environment. It will be appreciated, of course, that the use of such thermal conductors 409 allows the heat sources 405 to be thermally managed wherever they are disposed within the device 401, and thus permits significant design flexibility.

FIG. 10 depicts a particular, non-limiting embodiment of a modular synthetic jet ejector 501 in accordance with the teachings herein. The synthetic jet ejector 501 depicted therein includes a diaphragm 503, a chassis 505 and a surround 507 which extends between the diaphragm 503 and the chassis 505. The chassis 505 is equipped with mechanical features 509 and nozzle features 511 on first and second sides thereof, and is also equipped with electrical terminals 513.

In use, almost any number of instances of modular synthetic jet ejectors which are the same as, or similar to, the type depicted in FIG. 10 may be attached in a variety of ways as shown in FIG. 11 by using the mechanical features (element 509 in FIG. 10) to secure the instances of the modular synthetic jet ejector 602 together. Thus, for example, the modular synthetic jet ejector 602 may be connected in a side-to-side fashion as in the first configuration 601, or may be stacked as in the second configuration 603, to provide twice the flow. The third 605 and fourth 607 configurations illustrate the effect of adding additional instances of the modular synthetic jet ejectors 602 to the foregoing configurations.

Several variations are possible with respect to the devices and methodologies disclosed herein. For example, the modular synthetic jet ejectors disclosed herein may be assembled into various articles through various means. In addition to the use of mechanical features to secure the modular units together, various adhesives or fasteners may also be used for this purpose, alone or in addition to such mechanical features. By way of example, in some embodiments, mechanical features may be used to register the modular unit with another modular unit or with a host device or substrate, and a suitable adhesive or fastener may be utilized to fasten the modular units together, or to fasten the modular units to a host device or substrate.

It will further be appreciated that the modular synthetic jet ejector units disclosed herein may be attached or assembled into various devices having various shapes. For example, the resulting device may be L-shaped or T-shaped.

It will also be appreciated that the devices disclosed herein may be powered or controlled by a host device. By way of example, such devices may be incorporated into mobile technology platforms such as, for example, cell phones, smart phones, tablet PCs, and laptop PCs, and may be controlled by the electronic circuitry of the host device. The operating parameters of the incorporated device may be accessible by the host operating system so that the device can be controlled or programmed by software resident on the device. For example, the frequency at which a diaphragm in an incorporated synthetic jet ejector vibrates may be a programmable variable accessible by software operating on the host device.

It will also be appreciated that the devices disclosed herein may have synthetic jet actuators whose chambers are formed by one or more surfaces of the host device. By way of example, the modular synthetic jet actuators disclosed herein may have a chamber with a first surface formed by the host device motherboard, and a second surface formed by the host device chassis.

It will further be appreciated that the devices and methodologies disclosed herein may be utilized to cool or provide thermal management to a variety of heat sources. These include, but are not limited to, any of the components of computers (including those disclosed in the laptop computer of FIG. 2) or computational devices, including the components of laptop computers, desktop computers, and handheld computers or devices such as, for example, mobile phones or personal digital assistants (PDAs).

It will also be appreciated that various dimensions may be utilized in the channels and passageways in the devices and methodologies disclosed herein and illustrated, for example, in FIG. 4. In some embodiments, the tops of heat sources disposed in such passageways are spaced apart from the opposing surface of the passageway by a distance which is preferably within the range of about 0.75 mm to about 1.25 mm, more preferably within the range of about 0.85 mm to about 1.15 mm, and most preferably by a distance of about 1 mm. These passageways preferably have channels with first and second opposing surfaces which are spaced apart by a distance within the range of about 3 mm to about 9 mm, which are more preferably spaced apart by a distance within the range of about 5 mm to about 7 mm, and which are most preferably spaced apart by a distance of about 6 mm. These passageways preferably have a width within the range of about 25 mm to about 50 mm, more preferably have a width of about 30 mm to about 40 mm, and most preferably have a width of about 35 mm.

It will also be appreciated that the foregoing passageways may have various geometries. Thus, for example, while it is preferred that these passageways have a geometry that is rectangular in cross-section, embodiments are possible in which the passageway has a geometry that is circular, elliptical, polygonal, or irregular in cross-section.

Finally, it will be appreciated that various types of synthetic jet ejectors may be utilized in the foregoing devices and methodologies. These include synthetic jet ejectors which are based on voice coil technologies, as well as those based on piezoelectric or piezoceramic actuators.

The above description of the present invention is illustrative, and is not intended to be limiting. It will thus be appreciated that various additions, substitutions and modifications may be made to the above described embodiments without departing from the scope of the present invention. Accordingly, the scope of the present invention should be construed in reference to the appended claims.

1. A device, comprising:
a plurality of heat sources arranged in a channel, wherein each heat source has a top; and
a synthetic jet ejector disposed in said channel;
wherein said synthetic jet ejector directs a synthetic jet across the tops of said heat sources.

2. The device of claim 1, wherein each heat source is a semiconductor chip.

3. The device of claim 2, wherein said channel has first and second major opposing surfaces, wherein said plurality of semiconductor chips are disposed on said first surface, and wherein the tops of said semiconductor chips are spaced apart from said second major surface.

4. The device of claim 3, wherein said channel is essentially rectangular in cross-section.

5. The device of claim 3, wherein said device is a computer comprising a motherboard, and wherein said second major surface is a major surface of said motherboard.

6. The device of claim 5, wherein said heat sources are selected from the group consisting of processing cores and memory units.

7. The device of claim 5, wherein said computer is a laptop computer.

8. The device of claim 5, wherein the tops of said semiconductor chips are spaced apart from said second major surface by a distance within the range of 0.75 mm and 1.25 mm.

9. The device of claim 5, wherein the tops of said semiconductor chips are spaced apart from said second major surface by a distance within the range of 0.85 mm and 1.15 mm.

10. The device of claim 5, wherein the tops of said semiconductor chips are spaced apart from said second major surface by a distance of about 1 mm.

11. The device of claim 5, wherein said first and second major surfaces are spaced apart by a distance within the range of about 3 mm to about 9 mm.

12. The device of claim 5, wherein said first and second major surfaces are spaced apart by a distance within the range of about 5 mm to about 7 mm.

13. The device of claim 5, wherein said first and second major surfaces are spaced apart by a distance of about 6 mm.

14. The device of claim 5, wherein said channel has a width of about 25 mm to about 50 mm.

15. The device of claim 5, wherein said channel has a width of about 30 mm to about 40 mm.

16. The device of claim 5, wherein said channel has a width of about 35 mm.

17. A computer, comprising:
a plurality of heat sources;
a heat sink spaced apart from said heat sources;
a plurality of thermal conductors, each of which is in thermal contact with said heat sink and one of said heat sources; and
a synthetic jet ejector which directs a synthetic jet onto or across a surface of said heat sink.

18. The computer of claim 17, wherein at least one of said plurality of thermal conductors comprises graphene.

19. The computer of claim 17, wherein said heat sink includes a plurality of heat fins, and wherein said synthetic jet ejector directs each of a plurality of synthetic jets along the longitudinal axis of a channel formed by a pair of adjacent heat fins.

20. The computer of claim 17, wherein said synthetic jet ejector also serves as an acoustical speaker for the computer.

21. The computer of claim 17, wherein said computer is a handheld computer.

22. A synthetic jet ejector, comprising:
a diaphragm; and
a chassis having first and second major surfaces which are equipped with a first set of interlocking features such that a first instance of the synthetic jet ejector releasably attaches to a second instance of the synthetic jet ejector by way of said first set of interlocking features.

23. The synthetic jet ejector of claim 22, wherein said diaphragm is attached to said chassis by way of a surround.

24. The synthetic jet ejector of claim 22, wherein said chassis has a sidewall, and further comprising first and second electrical terminals disposed along said sidewall.

25. The synthetic jet ejector of claim 24, wherein said first and second terminals power said synthetic jet ejector when they are attached to an external power source.

26. The synthetic jet ejector of claim 24, wherein said sidewall is equipped with a second set of interlocking features such that a first instance of the synthetic jet ejector releasably attaches to a second instance of the synthetic jet ejector by way of said second set of interlocking features interlocking features.

27. The synthetic jet ejector of claim 26, wherein said first set of interlocking features is selected from the group consisting of protrusions and indentations.

28. The synthetic jet ejector of claim 27, wherein said second set of interlocking features is selected from the group consisting of protrusions and indentations.

29. The synthetic jet ejector of claim 22, wherein said chassis has a sidewall, wherein said sidewall has a first set of nozzle features defined in a first edge thereof, and wherein said sidewall has a second set of nozzle features defined in a second edge thereof.

30. The synthetic jet ejector of claim 29 wherein, when a first instance of the synthetic jet ejector releasably attaches to a second instance of the synthetic jet ejector by way of said first set of interlocking features, the first and second sets of nozzle features define a set of nozzles in the resulting construct.
